(19) United States
(12) Patent Application Publication
(10) Pub. No.: US 2026/0331414 A1
(43) Pub. Date: Oct. 22, 2026

(54) Carrying Container

(71) Applicant: Hitachi High-Tech Corporation, Minato-ku, Tokyo (JP)

(72) Inventors: Naofumi KOBAYASHI, Tokyo (JP); Kazuki ISHIZAWA, Tokyo (JP)

(21) Appl. No.: 19/491,031

(22) PCT Filed: Jun. 13, 2023
(86) PCT No.: PCT/JP2023/021982

§ 371 Date: Dec. 8, 2025

(51) Int. Cl. H01J 37/16; H01J 37/20

(52) U.S. Cl. CPC H01J 37/16; H01J 37/20; H01J 2237/20

(57) ABSTRACT

A carrying container includes a storage container SC and a cover CV. The storage container SC includes, in an upper surface SCa thereof, a storage groove portion SG configured to store a metal mesh MS on which a sample SM is placed. The cover CV is a transparent resin member and includes a conductor layer CL provided on an inner surface CVb thereof. The upper surface of the storage container SC including the storage groove portion SG includes a surface layer MC that is a metal member. In a state where the cover CV is attached to the storage container SC, the conductor layer CL of the cover CV is in contact with the surface layer MC of the storage container SC.

### TECHNICAL FIELD

The present invention relates to a carrying container, more particularly to a mesh carrying container.

### BACKGROUND ART

In recent years, the miniaturization of semiconductor devices has been progressing. In particular, for a semiconductor device having a three-dimensional structure, high integration technology has been dramatically advanced. In order to analyze these semiconductor devices, observation using a transmission electron microscope (TEM) or a scanning transmission electron microscope (STEM) has been increasing.

When observing a semiconductor device sample by the TEM, first, a wafer is processed using a processing device such as a focused ion beam (FIB) device to prepare a sample. In recent semiconductor device observation, the sample is processed into a thin piece and placed on a metal mesh or the like including a sample placement grid. The mesh on which the sample is placed is stored in a mesh carrying container (hereinafter, referred to as a “carrying container”), carried to the TEM, then transferred to a mesh placement holder (hereinafter, referred to as a “holder”) and inserted into the TEM, thereby observing the sample.

When moving the mesh, on which the sample is placed, between the FIB device and the TEM, it is necessary to carry the mesh while preventing damage to the sample or adhesion of dust to the sample.

JP2007-39106A (PTL 1) discloses a mesh carrying container. The mesh carrying container includes a base that stores an elastic sheet-like member and a cover that covers the base. A mesh to which a sample is attached is inserted into a cut of the sheet-like member.

### CITATION LIST

### Patent Literature

PTL 1: JP2007-39106A

### SUMMARY OF INVENTION

### Technical Problem

According to the study of the inventors of the present application, it has been found that when removing the cover from the base, the mesh to which the sample is attached falls outside the carrying container and the sample is damaged. That is, there is a demand for a carrying container that prevents damage of a sample.

Other technical problems and novel features will become apparent from descriptions of the present description and the accompanying drawings.

### Solution to Problem

A carrying container according to an embodiment is configured including: a storage container including an upper surface and a storage groove portion that is provided in the upper surface and stores a metal mesh on which a sample is placed; and a cover that is a transparent resin member and includes an inner surface and a conductor layer provided on the inner surface. The upper surface of the storage container including the storage groove portion includes a surface layer mainly formed of a metal member. In a state where the cover is attached to the storage container, the conductor layer of the cover is in contact with the surface layer of the storage container.

A carrying container according to an embodiment is configured including: a storage container including an upper surface and a storage groove portion that is provided in the upper surface and stores a metal mesh on which a sample is placed; and a cover mainly formed of a first metal member and including an outer surface, an inner surface, and a plurality of window portions running from the outer surface to the inner surface. The upper surface of the storage container including the storage groove portion includes a surface layer mainly formed of a second metal member. In each of the plurality of the window portions, a transparent resin member is disposed on an outer surface side, and a conductor layer is disposed on an inner surface side. In a state where the cover is attached to the storage container, the first metal member of the cover or the conductor layer is in contact with the surface layer of the storage container.

A carrying container according to an embodiment is configured including: a storage container including an upper surface and a first storage groove portion and a second storage groove portion, the first storage groove portion and the second storage groove portion each being provided in the upper surface and configured to store a metal mesh on which a sample is placed; and a cover mainly formed of a first metal member and including an outer surface, an inner surface, and a plurality of first small hole portions and a plurality of second small hole portions each running from the outer surface to the inner surface and having a circular shape. The upper surface of the storage container including the storage groove portions includes a surface layer mainly formed of a second metal member. The plurality of the first small hole portions and the plurality of the second small hole portions are covered with a transparent resin member at the outer surface of the cover. In a state where the cover is attached to the storage container, the first metal member of the cover is in contact with the surface layer of the storage container, and the plurality of the first small hole portions overlap the first storage groove portion and the plurality of the second small hole portions overlap the second storage groove portion in a plan view.

### Advantageous Effects of Invention

According to an embodiment, it is possible to provide a carrying container capable of preventing damage of a sample.

### BRIEF DESCRIPTION OF DRAWINGS

FIG. 1 is an external. view of a carrying container according to Embodiment 1.

FIG. 2 is a plan view of a storage container according to Embodiment 1.

FIG. 3 is a cross-sectional view taken along a line A-A in FIG. 2.

FIG. 4 is a plan view of a cover according to Embodiment 1.

FIG. 5 is a cross-sectional view taken along a line B-B in FIG. 4.

FIG. 6 is a plan view of the carrying container according to Embodiment 1.

FIG. 7 is a cross-sectional view taken along a line C-C in FIG. 6.

FIG. 8 is a plan view of a carrying container according to Modification 1.

FIG. 9 is a plan view of a carrying container according to Modification 2.

FIG. 10 is a cross-sectional view taken along a line D-D in FIG. 9.

FIG. 11 is a plan view of a carrying container according to Modification 3.

FIG. 12 is a cross-sectional view taken along a line E-E in FIG. 11.

FIG. 13 is a plan view of a carrying container according to Modification 4.

FIG. 14 is a cross-sectional view taken along a line F-F in FIG. 13.

FIG. 15 is a plan view of a carrying container according to Modification 5.

FIG. 16 is an enlarged view of small hole portions SH and SH1 shown in FIG. 15.

FIG. 17 is a cross-sectional view of a carrying container according to Modification 6.

FIG. 18 is a schematic diagram of a transfer device according to Embodiment 2.

FIG. 19 is a flowchart illustrating a transfer step according to Embodiment 2.

### DESCRIPTION OF EMBODIMENTS

Hereinafter, embodiments will be described in detail with reference to the drawings. In all the drawings for illustrating the embodiments, members having the same function are denoted by the same reference sign, and a repeated description thereof will be omitted. In the following embodiments, the description of the same or similar parts will not be repeated in principle unless particularly necessary. Further, hatching may be used even in a plan view.

### Embodiment

A carrying container is used when carrying a sample processed by a focused ion beam (FIB) to an observation apparatus such as a transmission electron microscope (TEM) or a scanning transmission electron microscope (STEM). By storing and carrying the sample in the carrying container, it is possible to prevent the sample from being damaged and prevent dust from adhering to the sample.

### Technical Issue of Related Art

First, a technical issue of the carrying container in the related art confirmed by the inventors of the present application will be described. A carrying container in the related art includes a storage container and a cover to which a screw is attached. The storage container is provided with a storage groove portion for storing a metal mesh on which a sample is placed, and a screw hole portion. By placing the cover on the storage container and attaching the cover to the storage container with the screw, the mesh on which the sample is placed is sealed in the storage groove portion.

In the carrying container in the related art, the storage container is made of nylon resin having excellent characteristics such as heat resistance, mechanical properties, and chemical resistance. On the other hand, the cover is made of an acrylic resin having high transparency. By forming the cover with a transparent resin member, it is possible to check, from the outside of the carrying container, whether the mesh is stored in the storage groove portion. A two-dimensional code or the like is printed on each of the mesh, the storage groove portion, and the carrying container, and the correspondence thereof is managed. However, a mistake such as the mesh not being stored in a designated storage groove portion or being stored in a wrong storage groove portion may occur. Therefore, before carrying the carrying container, it is confirmed from the outside of the carrying container that the mesh is stored in the storage groove portion, thereby preventing a transport mistake.

In the case of the carrying container in the related art, when the storage container and the cover come into contact with each other, movement of charges occurs. For example, negative charges tend to accumulate in the acrylic resin of the cover, and positive charges tend to accumulate in the nylon resin of the storage container. Since the metal mesh is stored in the storage container, the mesh is also charged with the positive charges of the storage container. When the cover is opened in this state, the positively charged mesh is attracted and adheres to the negatively charged cover. When the cover is removed, there is a possibility that the mesh adhered to the cover unexpectedly falls off, and the sample placed on the mesh is damaged or the mesh on which the sample is placed is lost.

As described above, a technical issue of the related art is to provide a carrying container that prevents damage or loss of a sample caused by charging of a cover or a storage container.

### Embodiment 1

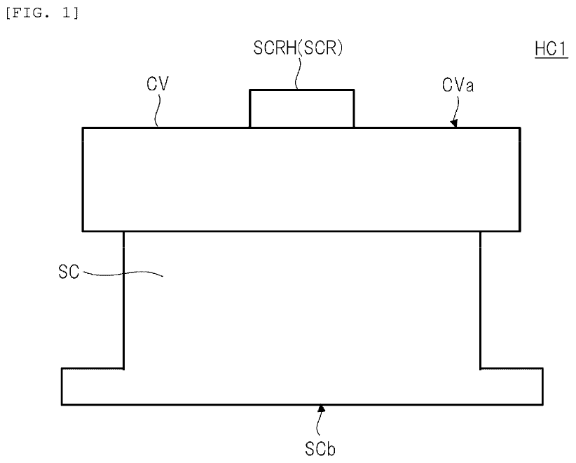

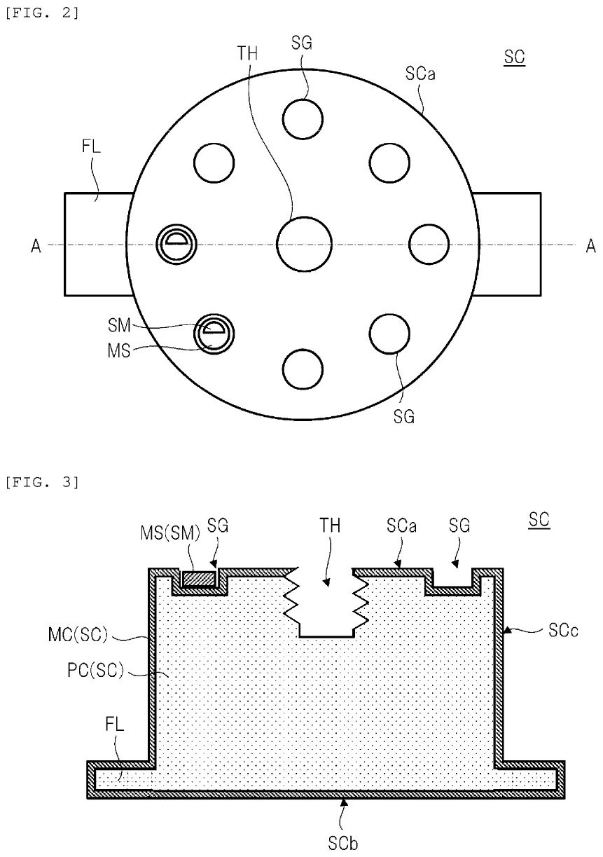

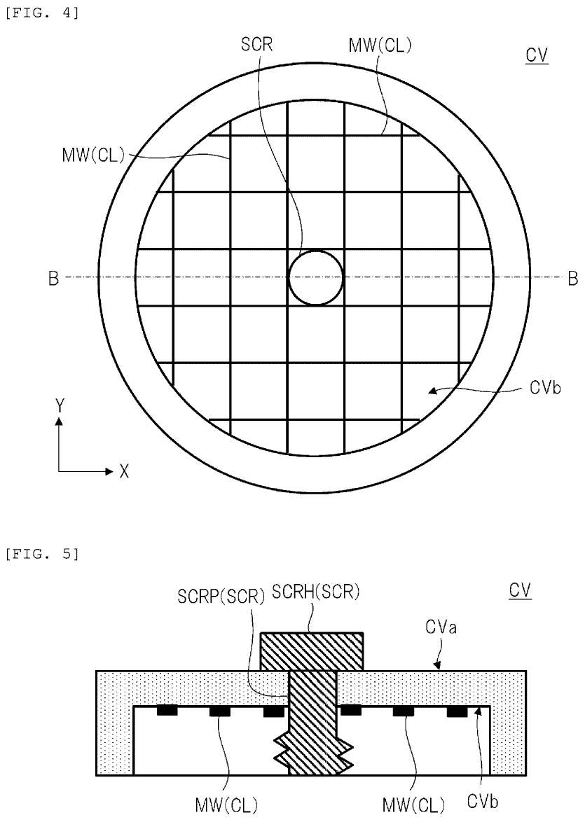

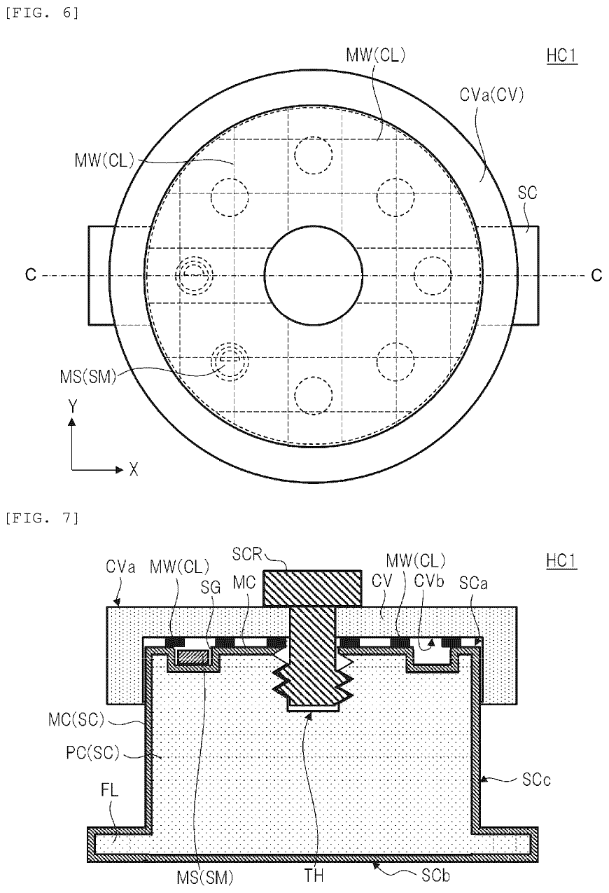

Hereinafter, a carrying container: HC1 according to Embodiment 1 will be described with reference to FIGS. 1 to 7. FIG. 1 is an external view of the carrying container according to Embodiment 1. FIG. 2 is a plan view of a storage container according to Embodiment 1. FIG. 3 is a cross-sectional view taken along a line A-A in FIG. 2. FIG. 4 is a plan view of a cover according to Embodiment 1. FIG. 5 is a cross-sectional view taken along a line B-B in FIG. 4. FIG. 6 is a plan view of the carrying container according to Embodiment 1. FIG. 7 is a cross-sectional view taken along a line C-C in FIG. 6.

As illustrated in FIG. 1, the carrying container HC1 includes a storage container SC, a cover CV, and a screw head SCRH provided at a central portion of an outer surface CVa of the cover CV.

The storage container SC will be described with reference to FIGS. 2 and 3. As illustrated in FIG. 3, the storage container SC has a columnar shape including an upper surface SCa, a lower surface SCb, and a side surface SCc. A protruding flange portion FL is provided on the side surface SCc closer to the lower surface SCb of the storage container SC. Further, a plurality of storage groove portions (mesh storage groove portions) SG and a screw hole portion TH are provided in the upper surface SCa. The storage groove portions SG and the screw hole portion TH are recessed with respect to the upper surface SCa. The storage container SC has a stacked structure formed of a main body PC having a large film thickness and a surface layer MC provided on a surface of the main body PC and having a smaller film thickness than the main body PC. The surface layer MC is provided all over the upper surface SCa, the lower surface SCb, and the side surface SCc including the flange portion FL of the storage container SC, and is provided all over the upper surface SCa excluding the screw hole portion TH. The surface layer MC is also provided in the storage groove portions SG so as to cover the surface of the main body PC. The surface layer MC may be provided in the screw hole portion TH to cover the surface of the main body PC. For example, the main body PC is mainly formed of a resin member made of a nylon resin or the like. For example, the surface layer MC is mainly formed of a metal member made of copper, aluminum, or stainless steel. The storage container SC may have a structure in which the surface layer MC is not provided and the main body PC is mainly formed of a metal member (in other words, the surface layer MC and the main body PC are the same metal member), and the storage groove portions SG and the screw hole portion TH are provided in the main body PC. Further, the surface layer MC mainly formed of a metal member may be disposed on the main body PC mainly formed of a resin member, and the storage groove portions SG may be provided in the surface layer MC. In this case, the film thickness of the surface layer MC is larger than a depth of the storage groove portion SG. That is, the upper surface SCa of the storage container SC including the storage groove portions SG is the surface layer MC mainly formed of a metal member.

FIG. 2 is a plan view of the storage container SC as viewed from above the upper surface SCa. The screw hole portion TH is disposed at the center of the circular upper surface SCa, and the plurality of o circular storage groove portions SG are annularly disposed at predetermined intervals in a peripheral region of the upper surface SCa so as to surround the screw hole portion TH. In FIG. 2, a mesh MS on which a sample SM is placed is stored in two storage groove portions SG. The mesh MS is, for example, a metal disk, and is mainly made of copper, gold, molybdenum, nickel, or the like. As illustrated in FIG. 3, in the storage groove portion SG, the metal mesh MS is in contact with the surface layer MC mainly formed of a metal member.

The cover CV will be described with reference to FIGS. 4 and 5. As illustrated in FIG. 5, the cover CV has a cap shape (also referred to as a cylindrical shape) including an outer surface CVa and an inner surface CVb. For example, the cover CV is mainly formed of a transparent resin member made of an acrylic resin or the like. A screw SCR having a screw head portion (gripping portion) SCRH and a screw portion SCRP is attached to the cover CV. A conductor layer CL is provided on the inner surface CVb of the cover CV, and the conductor layer CL is a metal wiring MW or the like having a desired width.

FIG. 4 is a plan view of the cover CV viewed from the inner surface CVb side. The screw SCR is provided at the center of the circular inner surface CVb. Further, a plurality of the metal wirings MW are provided in a lattice shape on the circular inner surface CVb. The metal wirings MW extending in an X direction and a Y direction orthogonal to each other are coupled (connected) at intersections thereof. Although not illustrated, an annular metal wiring MW may be disposed in a peripheral portion of the circular inner surface CVb, and the metal wirings MW extending in the X direction and the Y direction may be coupled to the annular metal wiring MW.

The carrying container HC1 will be described with reference to FIGS. 6 and 7. FIGS. 6 and 7 illustrate a state in which the mesh MS on which the sample SM is placed is stored in the storage groove portion SG and the cover CV is attached to the storage container SC. As illustrated in FIG. 7, the cover CV is fixed to the storage container SC by the screw SCR, and the metal wirings MW (in other words, the conductor layer CL) provided on the inner surface CVb of the cover CV are pressure-bonded to the metal surface layer MC provided on the upper surface SCa of the storage container SC.

FIG. 6 is a plan view of the carrying container HC1 as viewed from the outer surface CVa side of the cover CV. When the cover CV and the storage container SC are charged to have different polarities, it is effective to reduce an interval between the metal wirings MW in order to shield an electric field generated therebetween. However, it is important to set the width and the interval of the metal wiring MW to the extent that visibility of an inside the carrying container HC1 can be secured.

Embodiment 1 has the following features.

In a state where the metal surface layer MC is disposed on the upper surface SCa of the storage container SC, the metal wirings MW (in other words, the conductor layer CL) are disposed on the inner surface CVb of the cover CV, and the cover CV is attached to the storage container SC, the metal wirings MW (in other words, the conductor layer CL) provided on the inner surface CVb of the cover CV are pressure-bonded to the surface layer MC provided on the upper surface SCa of the storage container SC. That is, even when the cover CV and the storage container SC are charged, the charges move between the cover CV and the storage container SC, and the cover CV and the storage container SC become electrically neutral. Since the metal mesh MS is in contact with the surface layer MC in the storage groove portion SG, the cover CV and the mesh MS are electrically neutral. Therefore, when removing the cover CV from the storage container SC, it is possible to prevent damage of the sample SM or loss of the mesh MS that occurs when the mesh MS on which the sample is placed is attracted and adhered to the cover CV and falls outside the carrying container HC1.

Since a space can be secured between the adjacent metal wirings MW by providing the metal wirings MW arranged in a lattice shape on the cover CV formed of a transparent resin member, the visibility of the inside of the carrying container HC1 can be secured.

Since the mesh MS on which the sample SM is placed is stored in the storage groove portion SG of the storage container SC, and the cover CV is attached (screwed and fixed) to the storage container SC so as to cover the storage groove portion SG, it is possible to prevent dust, moisture, and the like from adhering to the sample SM.

In the storage resin SC, the main body PC is a resin member, and the surface layer MC of the main body PC is a thin metal member, so that a reduction in weight of the storage container SC is achieved. Further, since the cover CV is a resin member, a reduction in weight of the carrying container HC1 is achieved, and the carrying container HC1 can be easily carried. Further, since the main body PC of the storage resin SC is made of a nylon resin having excellent mechanical properties, mechanical strength of the storage container SC can be secured, and the sample SM can be prevented from being damaged by a stress from the outside of the carrying container HC1.

### Modification 1

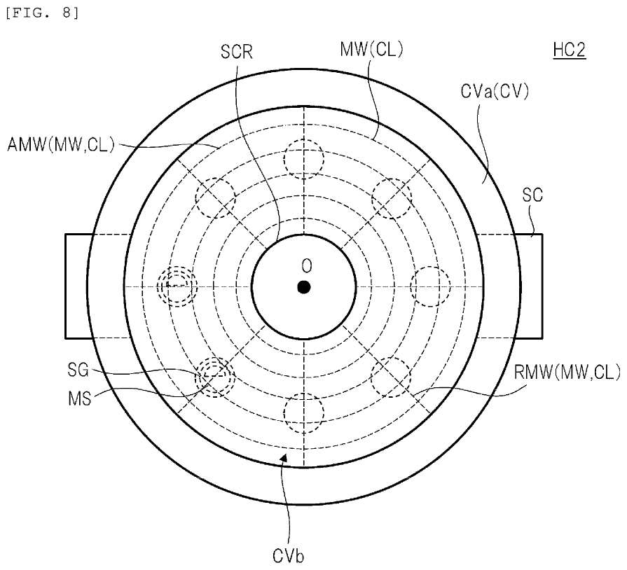

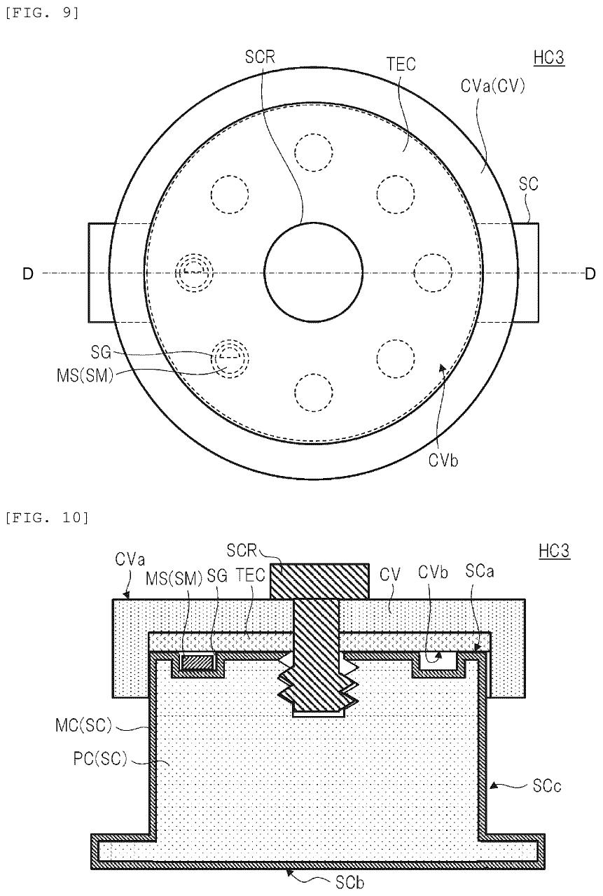

Modification 1 is a modification related to the metal wiring MW provided on the cover CV of the carrying container HC1 according to Embodiment 1, and a structure different from that of Embodiment 1 will be described. In Modification 1, the conductor layer CL includes an annular metal wiring AMW and a radial metal wiring RMW. FIG. 8 is a plan view of a carrying container HC2 according to Modification 1, and is a plan view of the carrying container HC2 as viewed from the outer surface CVa side of the cover CV.

The conductor layer CL is provided on the inner surface CVb of the cover CV, and the conductor layer CL includes a plurality of the annular metal wirings AMW and a plurality of the radial metal wirings RMW. The plurality of annular metal wirings AMW are arranged at equal intervals so as to form concentric circles with respect to a center O of the circular cover CV in the plan view. The plurality of annular metal wirings AMW are arranged at an interval such that two adjacent annular metal wirings AMW overlap the storage groove portion SG in the plan view. Further, the interval between two adjacent annular metal wirings AMW may be smaller than a diameter of the circular mesh MS. However, the interval between the two annular metal wirings AMW is set to such an extent that the visibility described above can be secured.

The plurality of radial metal wirings RMW extend radially with respect to the center O and couple (connect) the plurality of annular metal wirings AMW. Each of the plurality of radial metal wirings RMW electrically connects the plurality of annular metal wirings AMW. The annular metal wiring AMW and the radial metal wiring RMW are formed of the same metal member as that of the metal wiring MW in Embodiment 1. Similarly to Embodiment 1, in a state where the cover CV is attached to the storage container SC, the annular metal wirings AMW or the radial metal wirings RMW provided on the inner surface CVb of the cover CV are pressure-bonded to the surface layer MC provided on the upper surface SCa of the storage container SC. Therefore, Modification 1 has the same features as Embodiment 1.

Further, Modification 1 has the following features. When attaching the cover CV to the storage container SC by using the screw SCR, although the cover CV rotates with respect to the storage container SC, the mesh MS can be checked from between the two annular metal wirings AMW, disposed above the storage groove portion SG, regardless of a fixing position of the cover CV.

### Modification 2

Modification 2 is a modification related to the conductor layer CL provided on the cover CV of the carrying container HC1 according to Embodiment 1, and a structure different from that of Embodiment 1 will be described. In Modification 2, the conductive layer CL is a transparent conductive film TEC or the like. FIG. 9 is a plan view of a carrying container HC3 according to Modification 2, and is a plan view of the carrying container HC3 as viewed from the outer surface CVa side of the cover CV. FIG. 10 is a cross-sectional view taken along a line D-D in FIG. 9. As illustrated in FIGS. 9 and 10, the transparent conductive film TEC is provided on the inner surface CVb of the cover CV. As illustrated in FIG. 9, the transparent conductive film TEC covers the plurality of storage groove portions SG in the plan view. The transparent conductive film TEC is mainly made of indium tin oxide or zinc oxide. Similarly to Embodiment 1, in a state where the cover CV is attached to the storage container SC, the transparent conductive film TEC provided on the inner surface CVb of the cover CV is pressure-bonded to the surface layer MC provided on the upper surface SCa of the storage container SC. Therefore, Modification 2 has the same features as Modification 1.

Furthermore, according to Modification 2, since the transparent conductive film TEC is provided over the entire inner surface CVb of the cover CV, an electric field from a charged portion of the cover CV can be shielded more reliably.

### Modification 3

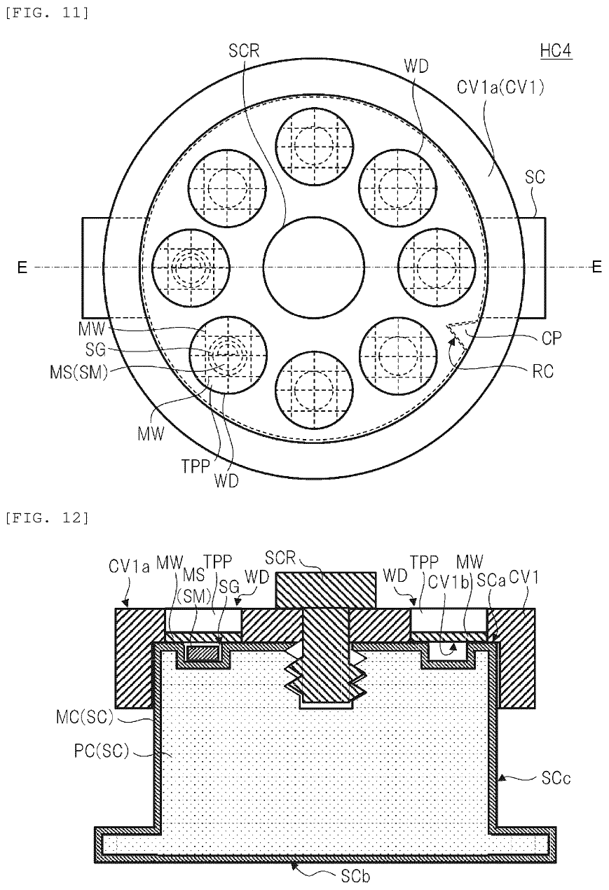

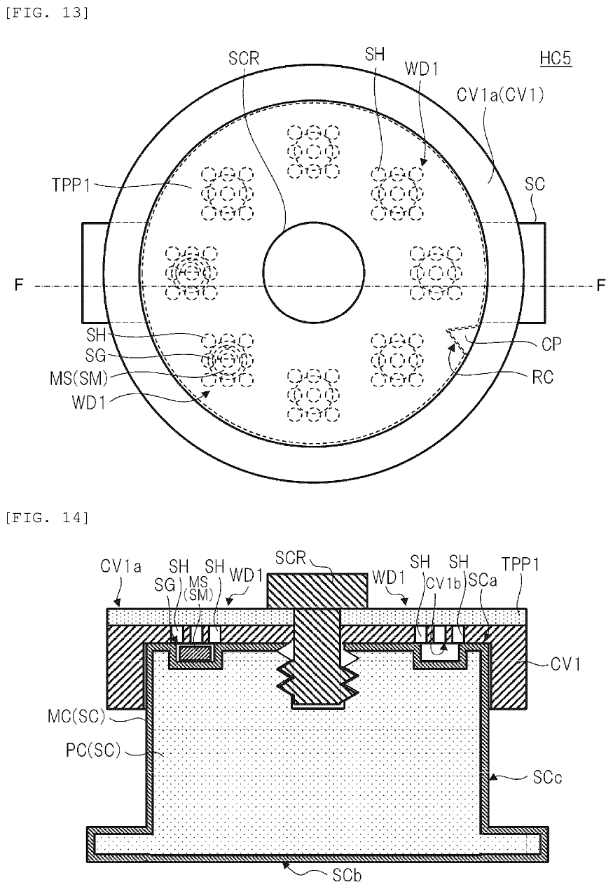

Modification 3 relates to the cover CV of the carrying container HC1 according to Embodiment 1. In Modification 3, a cover CV1 mainly formed of a metal member is used. FIG. 11 is a plan view of a carrying container HC4 according to Modification 3, and is a plan view of the carrying container HC4 as viewed from an outer surface CV1a side of the cover CV1. FIG. 12 is a cross-sectional view taken along a line E-E in FIG. 11.

As illustrated in FIGS. 11 and 12, the cover CV1 is a metal member, and a plurality of window portions WD are provided in the cover CV1. The plurality of window portions WD are annularly arranged around the screw SCR provided at the center of the cover CV1 and are separated from each other. The window portion WD is disposed so as to overlap the storage groove portion SG of the storage container SC in the plan view. A diameter of the circular window portion WD is designed to be larger than a diameter of the circular storage groove portion SG so that the storage groove portion SG is located inside the window portion WD of the cover CV1 when the cover CV1 is attached to the storage container SC. The window portion WD is an opening provided in the cover CV1, and a transparent resin member TPP and the metal wirings MW arranged in a lattice shape are embedded in the window portion WD. In the window portion WD, the transparent resin member TPP is provided on an outer surface CV1a side of the cover CV1, and the metal wirings MW are provided on an inner surface CV1b side of the cover CV1. For example, the cover CV1 and the metal wirings MW are mainly formed of metal members made of copper, aluminum, stainless steel, or the like. The transparent resin member TPP is mainly made of, for example, an acrylic resin. That is, the cover CV1 is mainly formed of a metal member, and includes the outer surface CV1a, an inner surface CV1b, and the plurality of window portions WD running from the outer surface CV1a to the inner surface CV1b. Further, in each of the plurality of window portions WD, the transparent resin member TPP is disposed on the outer surface CV1a side, and the conductive film CL is disposed on the inner surface CV1b side. Similarly to Embodiment 1, in a state where the cover CV1 is attached to the storage container SC, the metal wiring MW provided on the inner surface CV1b of the cover CV1 or the metal cover CV1 is pressure-bonded to the metal surface layer MC provided on the upper surface SCa of the storage container Sc. Therefore, Modification 3 has the same features as Embodiment 1.

In Modification 3, in order to arrange the storage groove portion SG inside the window portion WD of the cover CV1 when the cover CV1 is attached to the storage container SC, the cover CV1 is provided with a protrusion CP and the storage container SC is provided with a recess RC as illustrated in FIG. 11. When the cover CV1 is attached to the storage container SC, the protrusion CP of the cover CV1 is fitted into the recess RC of the storage container SC. In this way, the window portion WD of the cover CV1 and the storage groove portion SG of the storage container SC are aligned. Alternatively, the cover CV1 may be provided with the recess RC, and the storage container SC may be provided with the protrusion CP. That is, by providing a positioning part for each of the cover CV1 and the storage container SC, it is easy to check the mesh MS stored in the storage container SC from the outside of the carrying container HC4.

Further, in the window portion WD, since the transparent resin member TPP is disposed on the outer surface CV1a side of the cover CV1 and the metal wirings MW are disposed on the inner surface CV1b side of the cover CV1, the influence of the electric field generated by charging of the transparent resin member TPP on the mesh MS can be shielded by the metal wirings MW.

### Modification 4

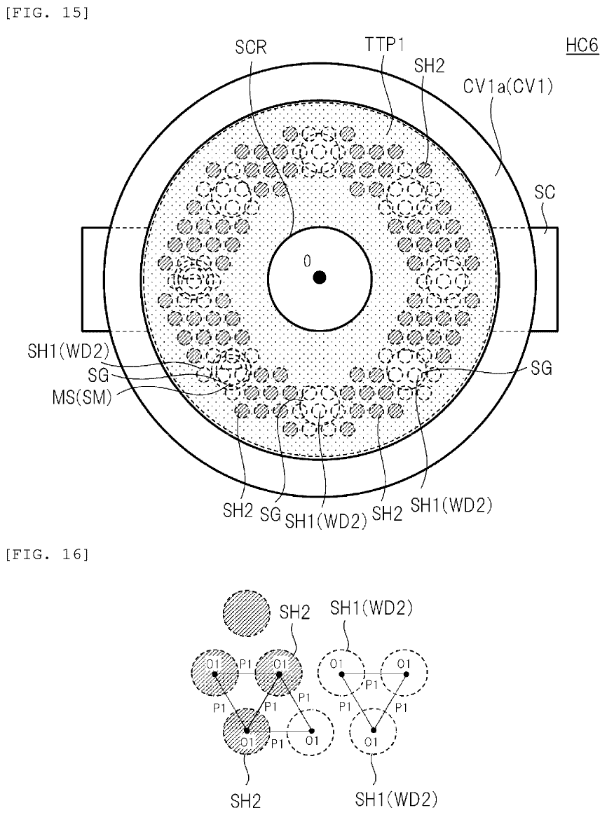

Modification 4 relates to the window portion WD of the cover CV1 in Modification 3. In Modification 4, the window portion WD1 has a plurality of small hole portions SH. FIG. 13 is a plan view of a carrying container HC5 according to Modification 4, and is a plan view of the carrying container HC5 as viewed from the outer surface CV1a side of the cover CV1. FIG. 14 is a cross-sectional view taken along a line F-F in FIG. 13.

As illustrated in FIGS. 13 and 14, the window portion WD1 for visually recognizing the mesh MS stored in the storage groove portion SG of the storage container SC includes the plurality of small hole portions SH arranged in a matrix. Each small hole portion SH penetrates the metal cover CV1, and is covered with a transparent resin member TPP1 on the outer surface CV1a side of the cover CV1. The transparent resin member TPP1 is mainly made of, for example, an acrylic resin. In the plan view, the plurality of small hole portions SH are arranged so as to overlap the storage groove portion SG of the storage container SC. That is, the cover CV1 is mainly formed of a metal member, and includes the outer surface CV1a, the inner surface CV1b, and the plurality of circular small hole portions SH running from the outer surface CV1a to the inner surface CV1b. Further, on the outer surface CV1a side of the cover CV1, the small hole portions SH are covered with the transparent resin member TPP1. Similarly to Embodiment 1, in a state where the cover CV1 is attached to the storage container SC, the metal cover CV1 is pressure-bonded to the metal surface layer MC provided on the upper surface SCa of the storage container SC. Therefore, Modification 4 has the same features as Embodiment 1.

Since the window portion WD1 has the plurality of small hole portions SH, it is easy to check the mesh MS stored in the storage container SC from the outside of the carrying container HC5.

Further, since the plurality of small hole portions SH provided in the window portion WD1 are covered with the transparent resin member TPP1, it is possible to prevent dust from adhering to the sample SM placed on the mesh MS.

Further, since a positioning part is provided for each of the cover CV1 and the storage container SC, it is easy to check the mesh MS stored in the storage container SC from the outside of the carrying container HC5 as in Modification 3.

### Modification 5

Modification 5 relates to the small hole portion SH of the cover CV1 in Modification 4. FIG. 15 is a plan view of a carrying container HC6 according to Modification 5, and is a plan view of the carrying container HC6 as viewed from the outer surface CV1a side of the cover CV1. FIG. 16 is an enlarged view of small hole portions SH1 and SH2 shown in FIG. 15. As illustrated in FIG. 15, the cover CV1 is provided with a plurality of window portions WD2, and each window portion WD2 is provided with a plurality of small hole portions SH1. The window portion WD2 for visually recognizing the mesh MS stored in the storage groove portion SG of the storage container SC has the plurality of small hole portions SH1. That is, in a state where the cover CV1 is attached to the storage container SC, the plurality of small hole portions SH1 provided in the window portion WD2 overlap the storage groove portion SG in the plan view. As illustrated in FIG. 16, the small hole portions SH1 are arranged at equal intervals with a pitch P1. The pitch is a distance between centers of two circular small hole portions SH1 adjacent to each other.

In Modification 5, the cover CV1 includes a plurality of auxiliary small hole portions SH2. The plurality of auxiliary small hole portions SH2 are provided in a region between adjacent window portions WD2 (in other words, a region between adjacent storage groove portions SG). As illustrated in FIG. 16, the plurality of auxiliary small hole portions SH2 are arranged at equal intervals with a pitch P1. The arrangement pitch P1 of the plurality of auxiliary small hole portions SH2 is equal to the arrangement pitch P1 of the plurality of small hole portions SH1. The small hole portions SH1 and the auxiliary small hole portions SH2 adjacent to each other are also arranged at equal intervals with the pitch P1. That is, the plurality of small hole portions SH1 and the plurality of auxiliary small hole portions SH2 are both arranged at equal intervals with the pitch P1. In FIGS. 15 and 16, in the plan view, the small hole portions SH1 overlapping the window portion WD2 are outlined, and the auxiliary small hole portions SH2 provided in the region between the adjacent window portions WD2 are hatched.

Similarly to the structure illustrated in FIG. 14 according to Modification 4, the small hole portions SH1 and the auxiliary small hole portions SH2 are also covered with the transparent resin member TPP1 in Modification 5.

According to Modification 5, the plurality of auxiliary small hole portions SH2 are provided in the region between the adjacent window portions WD2, and the arrangement pitch P1 of the auxiliary small hole portions SH2 is equal to the arrangement pitch P1 of the plurality of small hole portions SH1 provided in the window portion WD2. As a result, when the cover CV1 is attached to the storage container SC, even if a shift by rotation occurs, the visibility of the mesh MS from the outside of the carrying container HC6 can be secured.

Further, it is unnecessary to provide the positioning parts for the cover CV1 and the storage container SC described in Modification 4.

### Modification 6

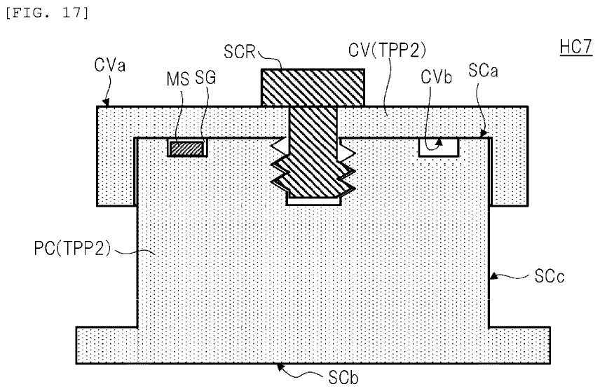

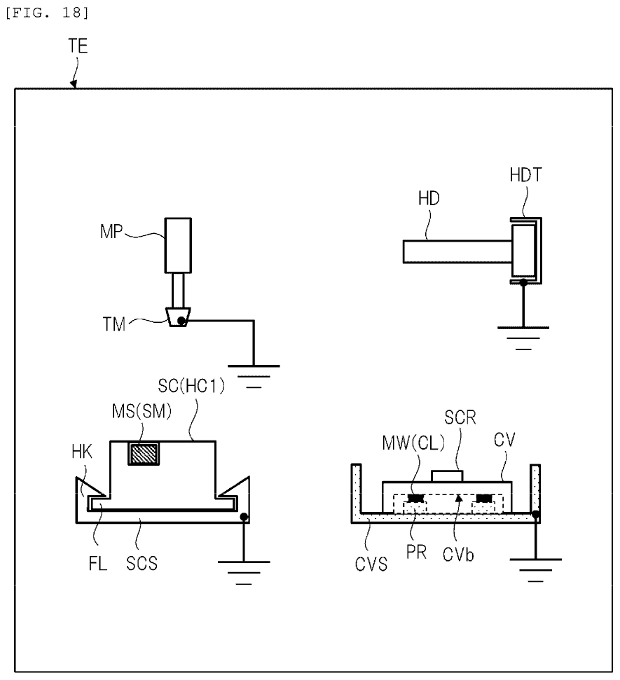

Modification 6 is a modification of Embodiment 1. FIG. 17 is a cross-sectional view of a carrying container HC7 according to Modification 6. As illustrated in FIG. 17, the storage container SC and the cover CV are mainly formed of the same transparent resin member TPP2. The transparent resin member TPP2 is mainly made of, for example, an acrylic resin. Since both the storage container SC and the cover CV are members in which negative charges are likely to accumulate, a potential difference is less likely to occur between the cover CV and the mesh MS stored in the storage groove portion SG of the storage container SC. Therefore, it is possible to prevent the mesh MS from falling off when the cover CV is opened.

### Embodiment 2

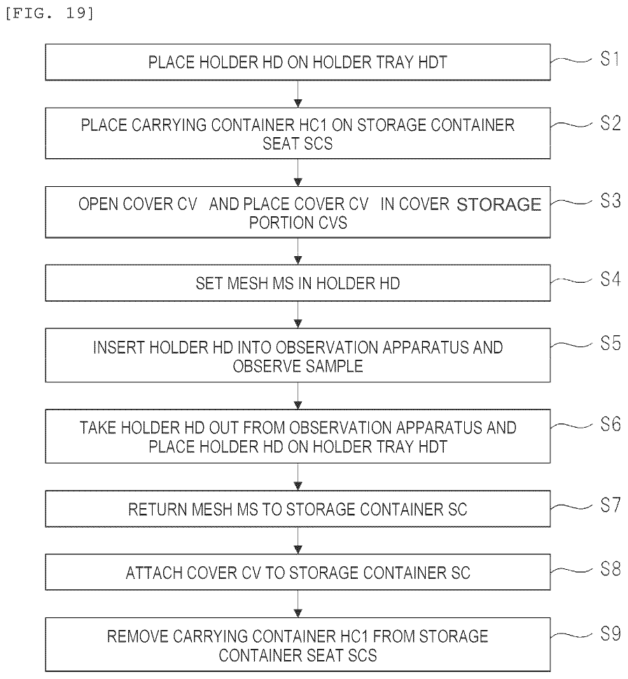

Embodiment 2 relates to a transfer device (mesh transfer device) and a transfer method (mesh transfer method) for transferring the mesh MS, which is stored and carried in the carrying container according to Embodiment 1, to a holder HD of an analysis device. FIG. 18 is a schematic diagram of the transfer device according to Embodiment 2. FIG. 19 is a flowchart illustrating a transfer process according to Embodiment 2.

As illustrated in FIG. 18, a transfer device TE includes a storage container seat SCS, a cover storage portion CVS, a holder tray HDT, a transfer mechanism TM, and a manipulator MP. The storage container seat SCS, the cover storage portion CVS, the holder tray HDT, and the transfer mechanism TM are mainly formed of a metal member, and are connected to the ground (ground potential).

Next, a transfer method will be described with reference to the flowchart of the transfer process in FIG. 19. First, the transfer device TE and the carrying container HC1 are prepared. Here, the description will be made using the carrying container HC1 according to Embodiment 1.

Next, step S1 shown in FIG. 19 is performed. That is, the holder HD is placed on the holder tray HDT. Here, the holder HD is a tool for inserting the sample SM into an observation apparatus such as the transmission electron microscope (TEM) or the scanning transmission electron microscope (STEM). Since the holder tray HDT is provided, when the holder HD is placed on the holder tray HDT, the metal holder HD is also grounded. It is sufficient that step S1 is performed before step S4 described later.

Next, step S2 and step S3 shown in FIG. 19 are performed. In step S2, the carrying container HC1 is placed on the storage container seat SCS. In step S3, the cover CV1 is opened and the cover CV1 is placed in the cover holding portion CVS. First, the carrying container HC1 illustrated in FIG. 7 is placed on the storage container seat SCS, and a hook HK of the storage container seat SCS is hooked on the flange portion FL of the storage container SC to fix the storage container SC to the storage container seat SCS. Next, the cover CV1 of the carrying container HC1 is opened, and the cover CV1 is placed in the cover holding portion CVS. As illustrated in FIG. 18, the cover holding portion CVS is provided with a protrusion PR, and the metal wiring MW that is the conductor layer CL provided on the inner surface CVb of the cover CV is in contact with the protrusion PR. That is, even if the cover CV is charged, the charges flow to the ground via the cover holding portion CVS.

When the carrying container HC1 illustrated in FIG. 7 is placed on the storage container seat SCS, charges accumulated in the carrying container HC1 in the step of carrying the carrying container HC1 flow to the ground via the grounded storage container seat SCS. The metal wiring MW (conductor layer CL) is provided on the inner surface CVb of the cover CV of the carrying container HC1, the storage container SC is covered with the surface layer MC that is a metal member, and the metal wiring MW (conductor layer CL) of the cover CV is in contact with the surface layer MC of the storage container SC. Therefore, the charges accumulated in the cover CV flow to the ground via the metal wiring MW, the surface layer MC, and the storage container seat SCS. In addition, when opening the cover CV, even if a charged operator touches the carrying container HC1, charges carried by the operator flow to the ground through the same path. Since the storage container SC in which the mesh MS is stored and the cover CV have the same potential (ground potential), it is possible to prevent the mesh MS from sticking to the cover CV and falling off when the cover CV is opened.

Next, step S4 and step S5 shown in FIG. 19 are performed. In step S4, by using the transfer mechanism TM and the manipulator MP illustrated in FIG. 18, the mesh MS on which the sample SM is placed is taken out from the storage container SC and set in the holder HD. Next, in step S5, the holder HD in which the mesh MS is set is inserted into the observation apparatus, and the sample is observed. In step S4, since the transfer mechanism TM is connected to the ground, sticking of the mesh MS to the transfer mechanism TM can be prevented. In step S5, since the holder HD is connected to the ground via the holder tray HDT, the mesh MS can be prevented from sticking to the holder HD.

Next, step S6 and step S7 shown in FIG. 19 are performed. When the sample observation is completed, the holder HD is taken out from the observation apparatus and placed on the holder tray HDT in step S6. Next, in step S7, by using the transfer mechanism TM and the manipulator MP illustrated in FIG. 18, the mesh MS set in the holder HD is removed and returned to the storage groove portion SG of the storage container SC.

Next, step S8 shown in FIG. 19 is performed. The cover CV is attached to the storage container SC in which the mesh MS is stored. Here, since the cover CV is connected to the ground via the cover holding portion CVS, the mesh MS can be prevented from sticking to the cover CV when attaching the cover CV.

Next, step S9 shown in FIG. 19 is performed. That is, the carrying container HC1 to which the cover CV is attached is removed from the storage container seat SCS, and a series of steps ends.

Although the transfer method using the carrying container HC1 according to Embodiment 1 has been described above in Embodiment 2, Embodiment 2 can be applied to the carrying containers HC2 to HC6 illustrated in Modifications 1 to 5.

Although the invention made by the present inventors has been specifically described based on the embodiments, the invention is not limited to the embodiments, and it is needless to say that various modifications can be made without departing from the gist of the invention. For example, the storage container and the cover each are not limited to a cylindrical shape, and may have a square shape or a rectangular shape. Graphite or the like can also be used as the conductor layer.

In addition, some of the contents described in the above embodiments will be described below.

### Appendix

### Appendix 1

A carrying container including:
a storage container including an upper surface and a storage groove portion that is provided in the upper surface and stores a metal mesh on which a sample is placed; and
a cover attached to the storage container, in which
the storage container and the cover are of a same transparent resin member.

### Appendix 2

The carrying container according to Appendix 1, in which
the transparent resin member is made of an acrylic resin.

### Appendix 3

A transfer device including:
a storage container seat configured to place a storage container storing a metal mesh on which a sample is placed;
a cover storage portion configured to place a cover to be attached to the storage container;
a holder tray configured to hold a holder; and
a manipulator including a transfer mechanism at a tip end thereof and configured to hold the mesh by the transfer mechanism to transfer the mesh between the storage container and the holder, in which
the storage container seat, the cover storage portion, the holder tray, and the transfer mechanism are connected to a ground potential.

### Appendix 4

A mesh transfer method including:
(a) preparing a carrying container including a storage container and a cover, the storage container including an upper surface and a storage groove portion that is provided in the upper surface and stores a metal mesh on which a sample is placed, the cover being a transparent resin member and including an inner surface and a conductor layer provided on the inner surface, the storage container having a stacked structure formed of a main body and a surface layer that is mainly formed of a metal member covering the main body, the conductor layer of the cover being in contact with the surface layer of the storage container in a state where the cover is attached to the storage container;
(b) preparing a transfer device, the transfer device including a storage container seat configured to place the storage container, a cover storage portion configured to place the cover, a holder tray configured to hold a holder, and a manipulator including a transfer mechanism at a tip end thereof and configured to hold the mesh by the transfer mechanism to transfer the mesh between the storage container and the holder, the storage container seat, the cover storage portion, the holder tray, and the transfer mechanism being connected to a ground potential;
(c) placing the carrying container on the storage container seat;
(d) removing the cover attached to the carrying container and placing the cover in the cover storage portion; and
(e) using the manipulator to hold the mesh by the transfer mechanism and set the mesh in the holder.

### Appendix 5

The mesh transfer method according to Appendix 4 further including:
(f) moving the mesh set in the holder to the storage container placed on the storage container seat; and
(g) attaching the cover placed in the cover storage portion to the storage container.

### Appendix 6

The mesh transfer method according to Appendix 5, in which
the cover storage portion is electrically connected to the conductor layer provided on the inner surface of the cover.

### Appendix 7

The mesh transfer method according to Appendix 4, in which
the main body of the storage container is a resin member.

### Appendix 8

The mesh transfer method according to Appendix 4, in which
the body and the surface layer of the storage container are the metal member.

### REFERENCE SIGNS LIST

AMW: Annular metal wiring
CL: Conductor layer
CP: Protrusion
CV, CV1: Cover
CVa, CV1a: Outer surface
CVb, CV1b: Inner surface
CVS: Cover storage portion
FL: Flange portion
HC1, HC2, HC3, HC4, HC5, HC6, HC7: Carrying container
HD: Holder
HDT: Holder tray
HK: Hook
MC: Surface layer
MP: Manipulator
MS: Mesh
MW: Metal wiring
C: Center point
PC: Main body
PR: Protrusion
RC: Recess
RMW: Radial metal wiring
SC: Storage container
SCa: Upper surface
SCb: Lower surface
SCc: Side surface
SCR: Screw
SCRH: Screw head portion (gripping portion)
SCRP: Screw portion
SCS: Storage container seat
SG: Storage groove portion (mesh storage groove portion)
SH, SH1: Small hole portion
SH2: Auxiliary small hole portion
SM: Sample
TE: Transfer device
TEC: Transparent conductive film
TM: Transfer mechanism
TPP, TPP1, TPP2: Transparent resin member
TH: Screw hole portion
WD, WD1, WD2: Window portion

1. A carrying container comprising:
a storage container including an upper surface and a storage groove portion that is provided in the upper surface and stores a metal mesh on which a sample is placed; and
a cover that is a transparent resin member and includes an inner surface and a conductor layer provided on the inner surface, wherein
the upper surface of the storage container including the storage groove portion includes a surface layer mainly formed of a metal member, and
in a state where the cover is attached to the storage container, the conductor layer of the cover is in contact with the surface layer of the storage container.

2. The carrying container according to claim 1, wherein
the conductor layer overlaps the mesh in a plan view.

3. The carrying container according to claim 1, wherein
entirety of the storage container is the metal member.

4. The carrying container according to claim 1, wherein
the storage container has a stacked structure formed of a resin member and the metal member covering a surface of the resin member.

5. The carrying container according to claim 4, wherein
the resin member of the storage container is made of a nylon resin, and the transparent resin member of the cover is made of an acrylic resin.

6. The carrying container according to claim 1, wherein
the metal member is mainly made of copper, aluminum, or stainless steel.

7. The carrying container according to claim 1, wherein
the conductor layer is a metal wiring arranged in a lattice shape on the inner surface of the cover.

8. The carrying container according to claim 1, wherein
the conductor layer is a plurality of annular metal wirings arranged concentrically on the inner surface of the cover.

9. The carrying container according to claim 8, wherein
an interval between adjacent ones of the annular metal wirings is smaller than a diameter of the mesh.

10. The carrying container according to claim 8, wherein
the conductor layer includes a radial metal wiring extending radially from a center of the cover, and
the radial metal wiring is connected to the plurality of the annular metal wirings.

11. The carrying container according to claim 1, wherein
the conductor layer is a transparent conductive film, and
the transparent conductive film covers the storage groove portion in a plan view.

12. The carrying container according to claim 11, wherein
the transparent conductive film is mainly made of indium tin oxide or zinc oxide.

13. A carrying container comprising:
a storage container including an upper surface and a storage groove portion that is provided in the upper surface and stores a metal mesh on which a sample is placed; and
a cover mainly formed of a first metal member and including an outer surface, an inner surface, and a plurality of window portions running from the outer surface to the inner surface, wherein
the upper surface of the storage container including the storage groove portion includes a surface layer mainly formed of a second metal member,
in each of the plurality of the window portions, a transparent resin member is disposed on a side of the outer surface, and a conductor layer is disposed on a side of the inner surface, and
in a state where the cover is attached to the storage container, the first metal member of the cover or the conductor layer is in contact with the surface layer of the storage container.

14. The carrying container according to claim 13, wherein
the conductor layer is a metal wiring arranged in a lattice shape.

15. The carrying container according to claim 13, wherein
the storage container includes a plurality of the storage groove portions,
the storage container includes a recess,
the cover includes a protrusion,
in a state where the cover is attached to the storage container, the protrusion and the recess are fitted with each other, and the window portions overlap the storage groove portions in a plan view.

16. A carrying container comprising:
a storage container including an upper surface and a first storage groove portion and a second storage groove portion, the first storage groove portion and the second storage groove portion each being provided in the upper surface and configured to store a metal mesh on which a sample is placed; and
a cover mainly formed of a first metal member and including an outer surface, an inner surface, and a plurality of first small hole portions and a plurality of second small hole portions each running from the outer surface to the inner surface and having a circular shape, wherein
the upper surface of the storage container including the first storage groove portions and the second storage groove portions includes a surface layer mainly formed of a second metal member,
the plurality of the first small hole portions and the plurality of the second small hole portions are covered with a transparent resin member at the outer surface of the cover, and
in a state where the cover is attached to the storage container, the first metal member of the cover is in contact with the surface layer of the storage container, and the plurality of the first small hole portions overlap the first storage groove portion and the plurality of the second small hole portions overlap the second storage groove portion in a plan view.

17. The carrying container according to claim 16, wherein
the storage container includes a recess,
the cover includes a protrusion, and
in a state where the cover is attached to the storage container, the protrusion and the recess are fitted with each other, and the plurality of the first small hole portions overlap the first storage groove portion and the plurality of the second small hole portions overlap the second storage groove portion in a plan view.

18. The carrying container according to claim 16, wherein
the cover includes a plurality of third small hole portions in a region between the plurality of the first small hole portions and the plurality of the second small hole portions, and
the plurality of the first small hole portions, the plurality of the second small hole portions, and the plurality of the third small hole portions are all arranged at an equal interval with an equal pitch.

19. The carrying container according to claim 18, wherein
the plurality of the third small hole portions are covered with the transparent resin member.
